(19) United States
(12) Patent Application Publication
(10) Pub. No.: US 2009/0001434 A1
(43) Pub. Date: Jan. 1, 2009

(54) Vertical Pin or Nip Photodiode and Method for the Production which is Compatible with a Conventional Cmos-Process

(75) Inventors: Konrad Bach, Tiefthal (DE); Wolfgang Einbrodt, Erfurt (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-FAB SEMICONDUCTOR FOUNDRIES AG, Erfurt (DE)

(21) Appl. No.: 11/718,364

(22) PCT Filed: Nov. 3, 2005
(86) PCT No.: PCT/DE05/01969

§ 371 Date: Jun. 9, 2008

(30) Foreign Application Priority Data
Nov. 3, 2004 (DE) 10 2004 053 077.7

(51) Int. Cl. H01L 27/146; H01L 31/105; H01L 31/18

(52) U.S. Cl. 257/292; 257/458; 438/59; 257/E27.133; 257/E31.061

(57) ABSTRACT

The invention relates to a fast photodiode and to a method for the production thereof in CMOS technology. The integrated PIN photodiode, which is formed or can be formed by CMOS technology, consists of an anode corresponding to a highly doped p-type substrate with a specific electric resistance of less than 50 mOhm*cm, a lightly p-doped l-region which is adjacent to the anode, and an n-type cathode which corresponds to the doping in the n-well region. The lightly doped l-region has a doping concentration of less than 10¹⁴ cm⁻³ and has a thickness of between 8 and 25 μm. The cathode region is completely embedded in the very lightly doped l-region. A distance from the edge of the cathode region to a highly doped adjacent region is in the range of 2.5 μm to 10 μm.

The invention relates to a fast operating integrated CMOS compatible photodiode and to the manufacturing thereof.

It is common practise to use the CMOS inherent diodes for the optical conversion of to signals. Without specific optimisation satisfactory results are achieved for a plurality of applications.

In the patent literature a plurality of specific configurations of such diodes are described for use in image sensor circuits. By means of specifically introduced implantations the is signal to noise ratio was enhanced, for example U.S. Pat. No. 6,514,785, TW-A 441 117 and GB-A 2 367 945.

Also, the enhancement of the fill factor as shown in EP-A 1 109 229 is to be seen under this aspect.

Other objects are the reduction of the quiet current and the enhancement of the spectral sensitivity, cf. U.S. Pat. No. 6,329,617.

Photodiodes fabricated according to CMOS technology usually exhibit the disadvantage that due to the deep penetration of light even after several 100 ns charge carriers are detected, which result in a restriction of the bandwidth to about 10 MHz. Differential approaches are described on the basis of which the slow signal portion is cut off, thereby, however, reducing sensitivity.

It is an object of the invention to overcome the deficiencies described above in view of the extended frequency range and thus to provide a fast photodiode.

According to one aspect of the present invention the object is solved by an integrated fast photodiode comprising a substrate that is highly doped with a dopant of a first conductivity type. Furthermore, the integrated fast photodiode comprises an adjacent l-region that is lightly doped with a dopant of the first conductivity type. Moreover, the integrated fast photodiode comprises an electrode region having a doping of a second conductivity type that is inverse to the first conductivity type, wherein a concentration of the doping corresponds to a well region formed in the substrate or to a source and a drain of a CMOS device formed in the substrate.

Due to this structure that corresponds to a PIN or NIP configuration an efficient photodiode may be formed in a CMOS compatible manner, since in particular the provision of the lightly doped l-region between the highly doped substrate and the well region and the drain and source regions, respectively, may be accomplished by processes for conventional CMOS devices without substantially compromising the other CMOS devices. Moreover, due to this arrangement compared to conventional photodiodes a strong electric field is also present within the l-region so that charge carriers generated by incident light may rapidly be discharged.

In a further preferred embodiment the lightly doped l-region has a dopant concentration of less than 1*10¹⁴ cm⁻³. This low doping concentration favours the appropriate shape of the field within the PIN or NIP structure so that a fast response behaviour is ensured upon incidence of light.

In a further embodiment the lightly doped l-region has a thickness of 8 μm to 25 μm. In this manner in combination with the very low dopant concentration the desired shape of the field and hence the desired response behaviour are obtained.

In a further embodiment the electrode region is located completely enclosed within the lightly doped l-region. Hence, an efficient behaviour is achieved during charge carrier accumulation.

In a further preferred embodiment the distance between the edge of the electrode region and an adjacent region of higher dopant concentration is 2.5 to 10 μm, in particular an adjacent well region. In this way a reliable delineation to adjacent CMOS devices is accomplished such that mutual interference is substantially avoided.

In a further embodiment the substrate is p-doped and has a specific electric resistivity of less than 0.05 Ohm*cm. Hence, the desired conductivity behaviour of the substrate acting as the anode may be achieved.

In a further embodiment the substrate is n-doped. Hence, an NIP structure is obtained for the fast photodiode. In this way respective photodiode structures may be implemented such that in total a high degree of flexibility is achieved when designing complex CMOS circuits.

In a further preferred embodiment the doping of the electrode region corresponds in type, amount and profile to the well region. Hence, the electrode region may be formed in a compatible manner during the fabrication of further CMOS devices.

In a further preferred embodiment the doping of the electrode region corresponds in type, amount and profile to the doping of drain and source (regions) of a CMOS device formed in the substrate. Hence, in particular a very high dopant concentration may be achieved without requiring a change of the manufacturing sequence for the other CMOS devices.

In a further preferred embodiment the l-region is provided as an epitaxial layer. In this manner the lightly doped l-region may be formed in an efficient manner without compromising the further manufacturing of the CMOS devices, since the epitaxial growth of the l-region may be performed prior to performing temperature sensitive processes during the CMOS production.

In a further embodiment the thickness of the l-region is determined in relation to the wavelength. The layer thickness of the e.g., epitaxially grown l-region may be optimally adjusted to a desired detection wavelength by controlling the growth process.

In a further advantageous embodiment the photodiode is integrated as a detector together with an evaluation circuit. Since in particular the fabrication of the fast photodiode in accomplished in a CMOS compatible fashion, complex evaluation circuits can be realised immediately together with the photodiode(s).

In a further embodiment the fast photodiode is integrated as a detector together with transimpedance amplifiers in evaluation circuits. Hence, a very efficient detector may be provided, wherein respective input amplifiers can be immediately formed by using the same process technology so that a fast responding arrangement with very low losses may be realised.

In a further embodiment the fast photodiode is integrated together with a plurality of further fast photodiodes of the same configuration and together with evaluation circuits for a plurality of channels. In this way a respective evaluation circuit even for sophisticated tasks including a plurality of signals to be evaluated may be realised.

According to another aspect the object is solved by an integrated fast PIN photodiode that is formed or is producible by CMOS technology, wherein the photodiode consists of an anode corresponding to the highly doped p-type substrate having a specific resistivity of less than 0.05 Ohm*cm and wherein an adjacent p-doped l-region and an n-type cathode corresponding to n⁺ doped areas of the source and the drain with respect to the doping are provided. In this context the lightly doped l-region has a dopant concentration of less than 10¹⁴ cm⁻³ and a thickness from 8 to 2 μm, wherein the cathode region is located completely enclosed in this very lightly doped l-region and wherein the distance between the edge of the cathode region to a higher doped adjacent region, in particular to an adjacent well region, is from 2.5 to 10 μm.

As stated above, due to this arrangement a very efficient photodiode is obtained, wherein in particular the cathode may be fabricated together with the respective drain and source regions of other CMOS devices.

According to another aspect the object is solved by an integrated fast PIN photodiode that is fabricated or may be fabricated by CMOS technology, wherein the photodiode consists of a highly doped p-type substrate having a specific electric resistivity of less than 0.05 Ohm*cm corresponding to the anode, and wherein an adjacent lightly p-doped l-region and an n-cathode having a doping that corresponds to the n-well are provided. The lightly doped l-region has dopant concentration of less than 1×10¹⁴ cm⁻³ and a thickness between 8 and 25 μm, wherein the cathode region is fully embedded in the very lightly doped l-region and wherein the distance of the edge of the cathode region to an adjacent region of increased dopant concentration, which in one embodiment represents an adjacent well region, is between 2.5 and 10 μm.

In this way the cathode region may be formed in a CMOS compatible manner in the context of an implantation of respective well regions.

According to a further aspect the object is solved by a method for forming an integrated fast photodiode, wherein the method comprises the fabrication of a lightly doped l-region above a highly doped substrate of the same conductivity type. Furthermore, an electrode region is formed above the l-region together with a well region or a drain and source region of a further CMOS device, wherein the electrode region is inversely doped relative to the substrata and the l-region.

In a further aspect a method for forming an integrated fast CMOS photodiode comprises forming a lightly doped l-region by epitaxy above a highly doped substrate of the same conductivity type and forming a highly doped electrode region above the l-region, wherein the electrode region is inversely doped compared to the substrate and the l-region.

As already explained above, the inventive method provides for the possibility to form the l-region in an adapted manner, for instance, in view of the wavelength to be detected, by well-established techniques, for example, by epitaxy, without significantly affecting the manufacturing sequence of other CMOS devices. On the other hand, forming the fast photodiode, in particular the respective electrode region acting as a cathode or an anode, depending on the type of substrate used, may be accomplished in combination with the implantation processes of the further CMOS devices.

In a further advantageous embodiment an implantation mask is used during the fabrication of the electrode region, wherein the implantation mask results in an offset of 2.5 to 10 μm to an adjacent region of a higher doping level, which in particular represents a well region. In this manner a concurrent fabrication of, e.g., a well region or drain and source regions and of the electrode region is possible, wherein at the same time a sufficiently large distance for reducing the mutual influence is obtained.

Advantageously, the implantation mask is configured such that the electrode region is fully embedded in the lightly doped l-region.

According to a further aspect a method for forming an fast PIN photodiode integrated by CMOS technology is provided. To this end the photodiode comprises the features as already previously described, wherein in particular the l-region is formed as an epitaxial layer having dopant concentration of less than 1*10¹⁴ cm⁻³ and a thickness in the range of 8 to 25 μm, wherein the cathode region is fully embedded in this very lightly doped l-region, wherein the distance of the edge of the cathode region to an adjacent region oh higher dopant concentration, which in one embodiment represents one of the well regions having a higher doping level, is between 2.5 and 10 μm.

According to another aspect of the present invention the object is solved by a method for forming a fast NIP photodiode integrated by CMOS technology, wherein the photodiode consists of a cathode corresponding to the highly doped n-type substrate having a specific electric resistivity of 0.05 Ohm*cm, an adjacent lightly n-doped l-region and a p-type anode with its doping corresponding to the p⁺-doped areas of the source and drain or the well region. Moreover, the lightly doped l-region is provided as an epitaxial layer having a dopant concentration of less than 1*10¹⁴ cm⁻³ and having a thickness between 8 and 25 μm, wherein the anode region is completely embedded in this very lightly doped l-region and wherein the distance of the edge of the anode region to an adjacent region of increased dopant concentration, which in one embodiment represents a well region, is in the range of 2.5 to 10 μm.

Advantageous embodiments are defined in the dependent claims.

The invention has the effect that the frequency range of the PIN photodiode may be extended to 1 GHz without significant additional effort in CMOS technology, without compromising the standard n-MOS and p-MOS transistors of the integrated circuit.

In the following the invention will be explained and completed by way of illustrative embodiments, while referring to the accompanying drawings. In the drawings:

FIG. 1 illustrate a schematic cross sectional view of an integrated PIN photodiode in CMOS technology according to one illustrative embodiment of the present invention,

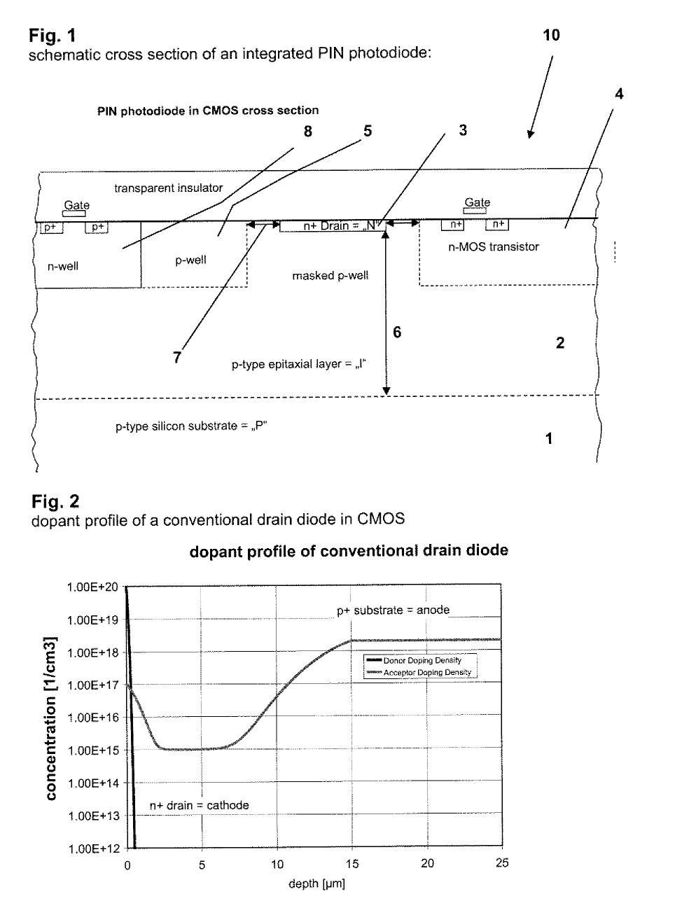

FIG. 2 shows a dopant profile of a conventional drain photodiode in CMOS technology,

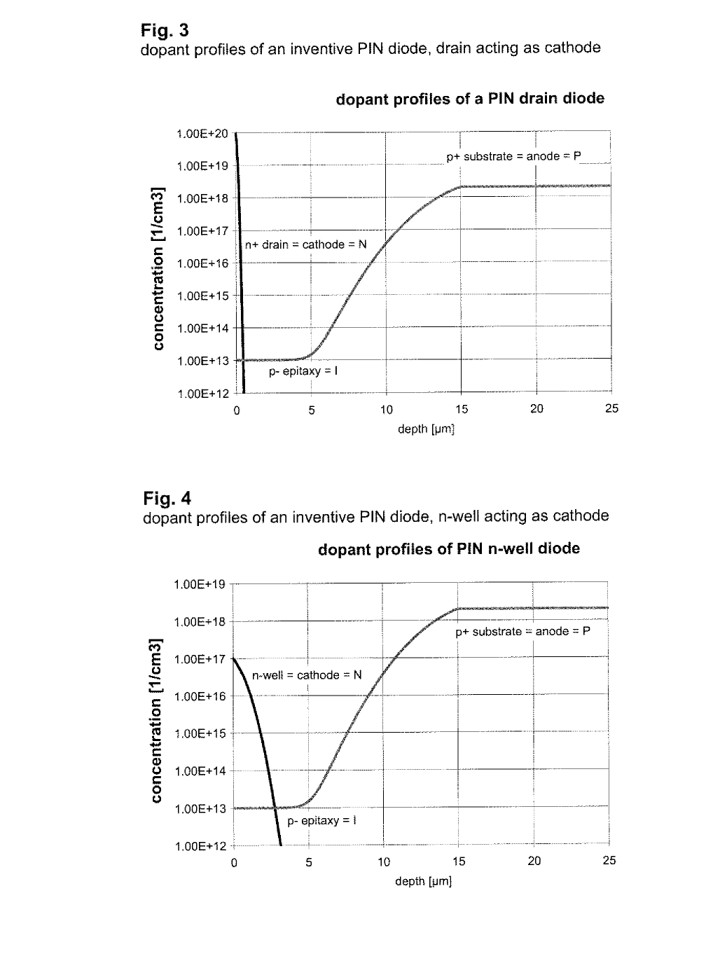

FIG. 3 illustrates the dopant profile of a PIN drain photodiode according to the present invention,

FIG. 4 depicts the dopant profile of an inventive PIN well photodiode,

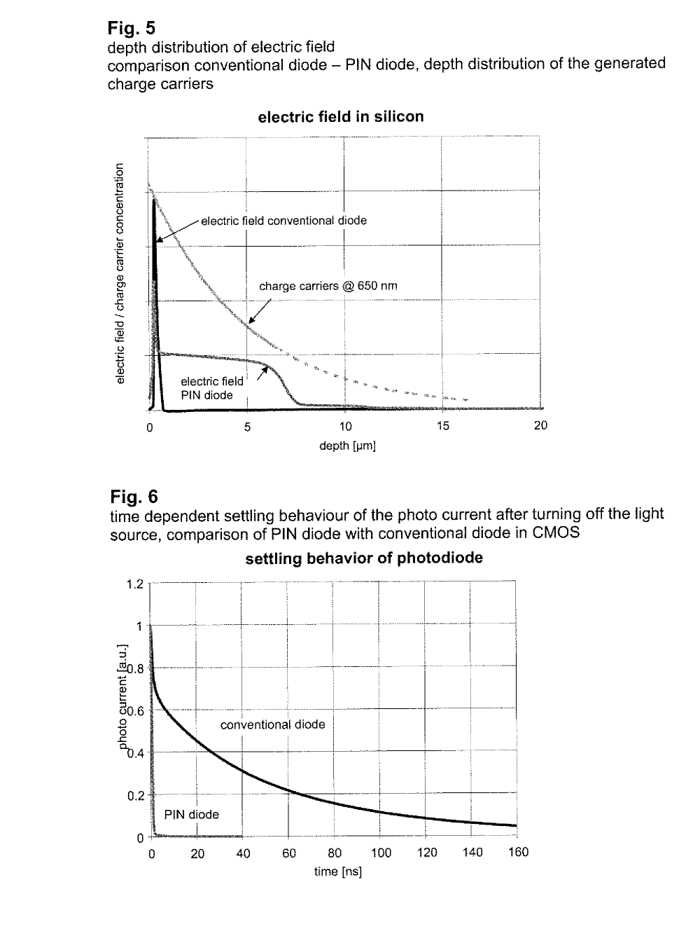

FIG. 5 the depth distribution of the electric field of the inventive PIN photodiode formed by CMOS technology in relation to the conventional photodiode and the depth distribution of the charge carriers created,

FIG. 6 shows the temporal settling behaviour of the photo current after turning off the light source, when comparing the inventive PIN photodiode with the conventional photodiode,

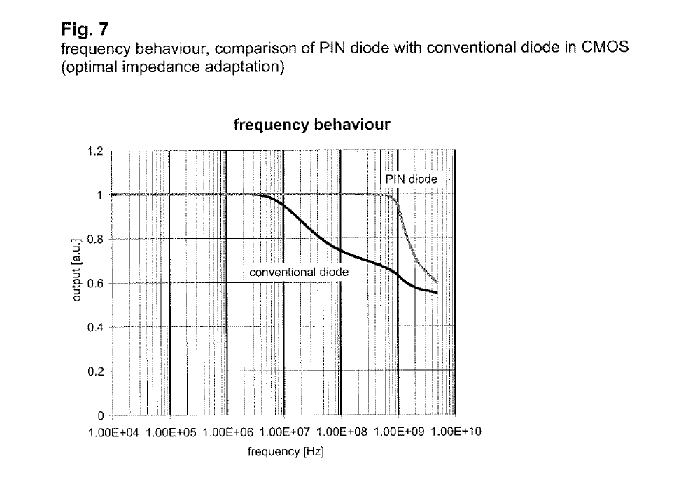

FIG. 7 depicts the frequency behaviour of the inventive PIN photodiode compared to the conventional photodiode.

In principle, the figures are self-explaining and would actually not require a detailed explanation. Nevertheless, the structure of an illustrative embodiment of a PIN photodiode will be briefly discussed.

FIG. 1 shows a CMOS device 10 comprising a substrate 1, which in the present embodiment is a highly doped p-type substrate and will be referred to in the following as a p-type region or anode. Moreover, the device 10 comprises a layer 2 referred to as a very lightly doped layer or as an l-region, wherein a dopant concentration may be less than approximately 1*10¹⁴ cm⁻³. In the present embodiment the l-region 2 is doped in the same manner as the p-type substrate 1. Furthermore, further CMOS devices, illustratively denoted as 4 and 5, are formed near the substrate surface of the device 10, wherein these devices comprise respective well or highly doped drain and source regions, for instance in the form of p-wells and n⁺ and p⁺ drain and source regions. Moreover, the l-region 2 is formed between the two adjacent p-well 4 and 5, wherein at the upper edge of the l-region 2 a highly doped region 3 is located that acts as an n-type region or a cathode in the present embodiment. In the embodiment shown in FIG. 1 the n-type region has a dopant concentration that corresponds to the n⁺ dopant concentrations of the respective n-MOS transistors in, for example, the p-well 4. In other embodiments that are not shown in FIG. 1 the n-type region 3 may have a doping that for instance corresponds to a doping of an n-well, as is for instance illustrated as n-well 8. Moreover, a thickness, denoted as 6, of the epitaxial layer, i.e., of the l-region 2 is in the range of approximately 8 to 25 μm, while an edge region 7 of the n-type region 3 with respect to adjacent p-well or n-wells of other CMOS devices has an extension that is in the range of approximately 2.5 to 10 μm. Hence, the n-type region or the cathode 3 is fully embedded in the l-region 2.

FIG. 3 depicts an exemplary distribution of the dopant concentration, wherein starting from the substrate, i.e., the p-type region 1, the concentration rapidly decreases when starting at a depth of approximately 15 μm, and has a value of 1*10¹⁴ cm⁻³ at a depth of about 7 to 8 μm, which decreases even further such that a pronounced junction is formed at the n-type region 3, wherein this region has a concentration that corresponds to the high concentration of drain and source regions.

FIG. 4 shows the respective dopant profile, wherein the n-type region 3 has the dopant concentration and the profile of the n-well region, for instance of the region 8. The progression of the dopant concentration in the l-region is substantially identical to the progression in FIG. 3.

FIG. 5 depicts a respective depth distribution of the electric field that is obtained, in particular at increased depths, by the arrangement P I N according to the present invention so that a corresponding collection of charge carriers may be accomplished in a highly efficient manner.

FIG. 6 shows the resulting settling behaviour of the photo current in relation to a conventional diode, thereby indicating that significantly higher frequencies may be processed.

PIN drain photodiode means that for the cathode the normal n⁺ drain doping is used. PIN well photodiode means that the normal n-well doping is used for the cathode.

The basis is a twin well CMOS technology in p-type silicon, preferably a p/p⁺ epitaxial material. Instead of usual epitaxial material having a specific electric resistivity of 10 to is 30 Ohm*cm, corresponding to approximately 5 to 10*10¹⁴ boron/cm⁻³, in the present invention a significantly more weakly doped epitaxial material is used. The doping level thereof is less than 1*10¹⁴ boron/cm⁻³ (corresponding to approximately 300 to 1000 Ohm*cm).

The thickness of the epitaxial layer 2 is in the range of 8 to 25 μm and should be selected with respect to the wavelength to be detected. As usual, a highly doped silicon having a dopant concentration of more than 1*10¹⁸ boron/cm⁻³ corresponding to a resistivity of less than 0.05 Ohm*cm is located below the epitaxial layer 2.

As a PIN photodiode an arrangement is effective:
P: highly doped p-type silicon
I: lightly doped p-type epitaxial layer
N: highly doped n-type region corresponding to n-type source or n-type drain regions or a respective n-well region having intermediate doping level

For maintaining the l-character of the middle layer, i.e., of the layer 2, the p-well must not be present in the diode region, that is, in the region laterally defined by the n-type region. In order to avoid the occurrence of an additional p-doping in this region, it is to be masked with the p-well mask that is present or in the case of a “self aligned” p-well an additional mask is to be used. This mask preferably extends laterally across and beyond the active photodiode region, that is, between the cathode region 3 and the PIN photodiode and the next well region advantageously a region 7 without an additional doping is provided, whose width is between 2.5 and 10 μm.

For large photodiodes (with an extension of several 10 μm) the n-type layer may either be doped homogenously across the entire area or may be provided with interruptions such that spatially alternatingly an N-type layer and a l-type layer are provided with a minimal width of the N layer and a width of the l-region of approximately 2.5 to 10 μm. This arrangement increases sensitivity for short wavelengths (blue light).

The normal n-MOS and p-MOS transistors of the CMOS technology are positioned in the p-wells and n-wells respectively, as usually, and will not be comprised by the changes in the initial material, as is experimentally confirmed.

FIG. 7 shows that under typical conditions the frequency characteristic of photodiodes in CMOS technology begins to significantly deteriorate at 10 MHz. Using the inventive structure the frequency range may be extended up to 1 GHz. The conditions vary depending on the wavelength and the thickness of the very lightly doped epitaxial layer. For an optimal selection of the thickness the frequency characteristic does not negatively affect sensitivity.

In this way very fast photodiodes may be monolithically integrated together with standard CMOS circuits. It is to be noted, however, that the anodes of the photodiodes, or for a NIP structure, the cathodes are connected. The most important application is fast data transmission in one or more channels (less than 1000).

It is within the scope of the present invention that also photodiodes of inverse doping, that is, so to say integrated PIN photodiodes as part of CMOS technology may be formed, having improved frequency data. In this case the conductivity type of the various doped regions, corresponding to the photodiode, are inverted, respectively.

We claim:

1. An integrated fast photodiode comprising a substrate that is highly doped with a dopant of a first conductivity type, and further comprising
an adjacent l-region that is lightly doped with a dopant of said first conductivity type,
an electrode region having a doping of a second conductivity type that is inverse to said first conductivity type, wherein a level of said doping corresponds to a well region formed in said substrate or to a source or drain of a CMOS device formed in said substrate.

2. The integrated fast photodiode of claim 1, wherein the lightly doped l-region has a dopant concentration of less than 1*10¹⁴ cm⁻³.

3. The integrated fast photodiode of claims 1 or 2, wherein the lightly doped l-region has a thickness between 8 and 25 μm.

4. The integrated fast photodiode of any of claims 1 to 3, wherein the electrode region is fully embedded in the lightly doped l-region.

5. The integrated fast photodiode of any of claims 1 to 4, wherein the distance from an edge of the electrode region to an adjacent well region is between 2.5 and 10 μm.

6. The integrated fast photodiode of any of claims 1 to 5 wherein the substrate is p-doped and has a specific electric resistivity of less than 50 mOhm*cm.

7. The integrated fast photodiode of any of claims 1 to 5, wherein the substrate is n-doped.

8. The integrated fast photodiode of any of claims 1 to 7, wherein the doping of the electrode region corresponds to the doping of the well region with respect to type, level and profile.

9. The integrated fast photodiode of any of claims 1 to 7, wherein the doping of the electrode region corresponds to the doping of drain and source of a CMOS device formed in the substrate with respect to type, level and profile

10. The integrated fast photodiode of any of claims 1 to 9, wherein the l-region is formed as an epitaxial layer.

11. The integrated fast photodiode of any of claims 1 to 10, wherein the thickness of the l-region is determined dependent on the wavelength.

12. The integrated fast photodiode of any of claims 1 to 11, integrated as a detector including an evaluation circuit.

13. The integrated fast photodiode of any of claims 1 to 11, integrated as a detector including transimpedance amplifiers in evaluation circuits.

14. The integrated fast photodiode of any of claims 1 to 10 and 13, integrated together with a plurality of photodiodes of the same configuration including evaluation circuits for a plurality of channels.

15. An integrated PIN photodiode produced or producible by a CMOS technology, comprising an anode corresponding to the highly doped p-type substrate having a specific electric resistivity of less than 50 mOhm*cm, an adjacent lightly p-doped l-region and an n-type cathode having a doping corresponding to the n⁺ doped areas of source and drain, wherein the lightly doped l-region has a dopant concentration of less than 10¹⁴ cm⁻³ and a thickness between 8 μm and 25 μm and the cathode region is fully embedded in said very lightly doped l-region, wherein the distance from an edge of the cathode region to an adjacent region of increased doping level is between 2.5 μm and 10 μm.

16. An integrated PIN photodiode produced or producible by a CMOS technology, comprised of an anode corresponding to the highly doped p-type substrate having a specific electric resistivity of less than 50 mOhm*cm, an adjacent lightly p-doped l-region and an n-type cathode having a doping corresponding to n-well region,
wherein the lightly doped l-region has a dopant concentration of less than 10¹⁴ cm⁻³ and a thickness between 8 μm and 25 μm and the cathode region is fully embedded in said very lightly doped l-region, wherein the distance from an edge of the cathode region to an adjacent region of increased doping level is between 2.5 μm and 10 μm.

17. A method of forming an integrated fast photodiode, the method comprising
forming a lightly doped l-region above a highly doped substrate of the same conductivity type,
forming an electrode region above said l-region together with a well device, wherein said electrode region is inversely doped compared to said substrate and said l-region or a drain region and a source region of a further CMOS region.

18. A method of forming an integrated fast photodiode, the method comprising
epitaxially forming a lightly doped l-region above a highly doped substrate of the same conductivity type,
forming a highly doped electrode region above said l-region, wherein said electrode region is inversely doped compared to said substrate and said l-region.

19. The method of claim 17, wherein the l-region is formed by an epitaxy process.

20. The method of claim 18, wherein the electrode region is formed together with a well region or a drain region and a source region of a further CMOS device.

21. The method of any of claims 17 to 20, wherein an implantation mask is used for forming the electrode region, and wherein said implantation mask causes a distance to the (next) region of increased doping level of 2.5 to 10 μm.

22. The method of claim 21, wherein said implantation mask is configured to position said electrode region in said lightly doped l-region so as to be fully embedded therein.

23. The method of any of claims 17 to 22, wherein the substrate is a p-type substrate having a specific electric resistivity of less than 0.05 Ohm*cm and serves as a further electrode, wherein said lightly doped l-region is formed with a dopant concentration of less than 10¹⁴ cm⁻³ and with a thickness between 8 and 25 μm.

24. A method of forming an integrated fast PIN photodiode in CMOS technology, comprised of an anode corresponding to the highly doped p-type substrate having a specific electric resistivity of less than 0.05 Ohm*cm, an adjacent lightly p-doped l-region and an n-type cathode having a doping corresponding to n⁺ doped areas of the source and drain,
wherein the lightly doped l-region is formed as an epitaxial layer having a dopant concentration of less than 1×10¹⁴ cm⁻³ and a thickness between 8 and 25 μm and the cathode region is fully embedded in said very lightly doped l-region, wherein the distance from an edge of the cathode region to a neighbouring region of increased doping level is between 2.5 μm and 10 μm.

25. The method of claim 24, wherein the n-type cathode of the PIN photodiode is formed with the same doping method, and in particular with the same doping level, as the n-well areas.

26. A production method of an integrated fast NIP photodiode formed in CMOS technology, comprised of a cathode corresponding to the highly doped n-type substrate having a specific electric resistivity of less than 0.05 Ohm*cm, an adjacent lightly n-doped l-region and an p-type anode having a doping corresponding to p⁺ doped areas of source and drain, wherein
the lightly doped l-region is formed as an epitaxial layer having a dopant concentration of less than 10¹⁴ cm⁻³ and a thickness between 8 and 25 μm;
the anode region is positioned so as to be fully embedded in said very lightly doped l-region, wherein the distance from the edge of the anode region to a neighbouring region of increased doping level is between 2.5 μm and 10 μm.
